(19) United States
(12) Patent Application Publication
(10) Pub. No.: US 2025/0357927 A1
(43) Pub. Date: Nov. 20, 2025

(54) LEVEL SHIFTERS, MEMORY, MEMORY SYSTEMS, AND ELECTRONIC APPARATUSES

(71) Applicant: Yangtze Memory Technologies Co., Ltd., Wuhan (CN)

(72) Inventors: Weiwei He, Wuhan (CN); Xinrui Wang, Wuhan (CN)

(73) Assignee: Yangtze Memory Technologies Co., Ltd., Wuhan (CN)

(21) Appl. No.: 18/937,861

(22) Filed: Nov. 5, 2024

(30) Foreign Application Priority Data
May 20, 2024 (CN) 202410627675.2

(51) Int. Cl. H03K 19/0185; G11C 16/04; G11C 16/06

(52) U.S. Cl. CPC H03K 19/018521; G11C 16/06; G11C 16/0483

(57) ABSTRACT

Examples of the present disclosure provide a level shifter, a memory, a memory system, and an electronic apparatus. The level shifter includes: an input circuit, a shifter and an output circuit that are coupled sequentially, wherein the input circuit is configured to generate a first input signal in response to a first level signal; and a regulation circuit coupled to the input circuit and the shifter separately, wherein the regulation circuit is configured to regulate a first control signal output by the shifter in response to the first input signal, wherein a voltage domain of the shifter is different from a voltage domain of the input circuit; and the output circuit is configured to output a second level signal in response to the regulated first control signal, wherein a voltage level of the second level signal is higher than a voltage level of the first level signal.

### CROSS-REFERENCE TO RELATED APPLICATION

This application claims priority to and the benefit of Chinese Patent Application 202410627675.2, filed on May 20, 2024, which is hereby incorporated by reference in its entirety.

### TECHNICAL FIELD

The present disclosure relates to the technical field of integrated circuits, and particularly to level shifters, memory, memory systems, and electronic apparatuses.

### BACKGROUND

In recent years, the integrated circuit industry has experienced rapid development. With the continuous progress of semiconductor manufacturing process, the feature sizes of semiconductor devices continue to decrease, and their integration density is increasing. Due to increasing demands on high performance, high speed, and multi-function of semiconductor devices in the consumer market, various devices in a semiconductor apparatus may operate in multiple different voltage domains.

### BRIEF DESCRIPTION OF THE DRAWINGS

FIG. 1 is a schematic diagram of a system having a memory provided by examples of the present disclosure;

FIG. 2A is a schematic diagram of a memory card provided by examples of the present disclosure;

FIG. 2B is a schematic diagram of a Solid State Drive (SSD) provided by examples of the present disclosure;

FIG. 3 is a schematic diagram of a memory provided by examples of the present disclosure;

FIG. 4 is a schematic diagram of a level shifter provided by examples of the present disclosure;

FIG. 5 is a timing diagram of each node level of a level shifter provided by examples of the present disclosure;

FIG. 6 is a schematic diagram of another level shifter provided by examples of the present disclosure;

FIG. 7 is a schematic diagram of a regulation circuit of another level shifter provided by examples of the present disclosure;

FIG. 8 is a circuit diagram of another level shifter provided by examples of the present disclosure;

FIG. 9 is a timing diagram of each node level of another level shifter provided by examples of the present disclosure;

FIG. 10 is a circuit diagram of yet another level shifter provided by examples of the present disclosure; and

FIG. 11 is a schematic diagram of a bias circuit in a page buffer provided by examples of the present disclosure.

### DETAILED DESCRIPTION

For ease of understanding of the present disclosure, example implementations of the present disclosure will be described below in more detail with reference to the relevant drawings. Although the example implementations of the present disclosure are shown in the drawings, it is to be understood that the present disclosure may be implemented in various forms and should not be limited by particular implementations as set forth herein. Rather, these implementations are provided for a more thorough understanding of the present disclosure, and can fully convey the scope of the present disclosure to those skilled in the art.

In the following description, numerous specific details are presented to provide a more thorough understanding of the present disclosure. However, it is apparent to those skilled in the art that the present disclosure may be implemented without one or more of these details. In some examples, in order to avoid confusion with the present disclosure, some technical features well-known in the art are not described; that is, not all features of actual examples are described herein, and well-known functions and structures are not described in detail.

In general, terminologies may be understood at least in part from usage in the context. For example, depending at least partially upon the context, the term “one or more” as used herein can be used to describe any feature, structure, or characteristic in a singular sense or can be used to describe a combination of features, structures, or characteristics in a plural sense. Similarly, depending at least partially upon the context, terms such as “a/an” or “the”, can also be understood as conveying a singular use or a plural use. In addition, depending at least partially upon the context, the term “based on” may be understood as being not necessarily intended to convey an exclusive set of factors and may, instead, allow existence of additional factors not necessarily described expressly.

The terms as used herein are only intended to describe the particular examples, and are not used as limitations to the present disclosure, unless otherwise defined. As used herein, unless otherwise indicated expressly in the context, “a”, “an” and “the” in a singular form are also intended to include a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

In order to understand the present disclosure thoroughly, detailed operations and detailed structures will be proposed in the following description to set forth the technical solution of the present disclosure. Detailed descriptions of the examples of the present disclosure are as follows. However, the present disclosure may also have other implementations in addition to these detailed descriptions.

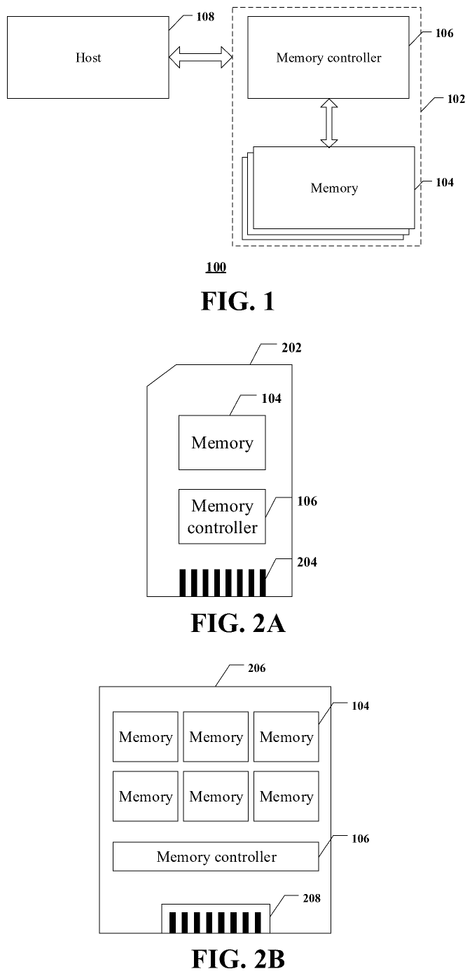

FIG. 1 shows a schematic diagram of an electronic apparatus 100 having a memory according to some aspects of the present disclosure. The electronic apparatus 100 may include a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein.

As shown in FIG. 1, the electronic apparatus 100 may comprise a host 108 and a memory system 102, and the memory system 102 has one or more memories 104 and a memory controller 106. The host 108 may be a processor of the electronic apparatus (such as a Central Processing Unit (CPU), or a System on Chip (SoC) (such as an Application Processor (AP)). The host 108 may be configured to send or receive data to or from the memory 104.

According to some implementations, the memory controller 106 is coupled to the memory 104 and the host 108, and is configured to control the memory 104. The memory controller 106 may manage data stored in the memory 104, and communicate with the host 108. In some implementations, the memory controller 106 is designed for operating in a low duty-cycle environment, such as Secure Digital (SD) memory cards, Compact Flash (CF) cards, Universal Serial Bus (USB) flash drives, or other media for use in electronic apparatuses, such as personal computers, digital cameras, mobile phones, etc. In some implementations, the memory controller 106 is designed for operating in a high duty-cycle environment of solid state drive or Embedded Multi Media Cards (eMMC) used as data memories for mobile apparatuses, such as smartphones, tablets, laptop computers, etc., and enterprise memory arrays.

The memory controller 106 may be configured to control operations of the memory 104, such as read, erase, and write (also referred to as program) operations. The memory controller 106 may be further configured to manage various functions with respect to data stored or to be stored in the memory 104, including, but not limited to, bad-block management, garbage collection, logical-to-physical address translation, wear leveling, etc. In some implementations, the memory controller 106 is further configured to process Error Correction Codes (ECC) with respect to the data read from or written to the memory 104. The memory controller 106 may further perform any other suitable functions, for example, formatting the memory 104. The memory controller 106 may communicate with a host (e.g., the host 108) according to a particular communication protocol. For example, the memory controller 106 may communicate with the host 108 through at least one of various interface protocols, such as a USB protocol, an MMC protocol, a Peripheral Component Interconnect (PCI) protocol, a Peripheral Component Interconnect Express (PCIE) protocol, an Advanced Technology Attachment (ATA) protocol, a serial-ATA protocol, a parallel-ATA protocol, a Small Computer System Interface (SCSI) protocol, an Enhanced Small Disk Interface (ESDI) protocol, an Integrated Drive Electronics (IDE) protocol, a Firewire protocol, etc.

The memory controller 106 and one or more memories 104 may be integrated into various types of storage apparatuses, for example, be comprised in the same package, such as a universal flash storage package or an eMMC package. That is to say, the memory system 102 may be implemented and packaged into different types of end electronic products. In one example shown in FIG. 2A, the memory controller 106 and a single memory 104 may be integrated into a memory card 202. The memory card 202 may comprise a PC (Personal Computer Memory Card International Association, PCMCIA) card, a CF card, a Smart Media (SM) card, a memory stick, a Multi Media Card (MMC), a Reduced-Size MMC (RS-MMC), a Multi Media Card Micro (MMCmicro), an SD card (SD, miniSD, microSD, SDHC), Universal Flash Storage (UFS), etc. The memory card 202 may further comprise a memory card connector 204 coupling the memory card 202 with a host (e.g., the host 108 in FIG. 1). In another example as shown in FIG. 2B, the memory controller 106 and the plurality of memories 104 may be integrated into an SSD 206. The SSD 206 may further comprise an SSD connector 208 coupling the SSD 206 with a host (e.g., the host 108 in FIG. 1). In some implementations, the storage capacity and/or operation speed of the SSD 206 are greater than those of the memory card 202.

In the examples of the present disclosure, the memory may be a NAND flash memory. However, it is to be understood that the level shifter provided by the present disclosure is not limited to be applied in the NAND flash memory, and may be applied to other types of memory devices, such as an Electrically Erasable Programmable Read-Only Memory (EEPROM), a NOR flash, a Phase Change Random Access Memory (PRAM), a magnetic RAM (MRAM), a resistive RAM (RRAM), a ferroelectric RAM (FRAM), etc. In some other examples, in addition to being applied in the memory, the level shifter provided by the present disclosure may be also applied in any other types of electronic apparatuses comprising a digital circuit, such as a processor, a controller, a programmable logic device, and the like.

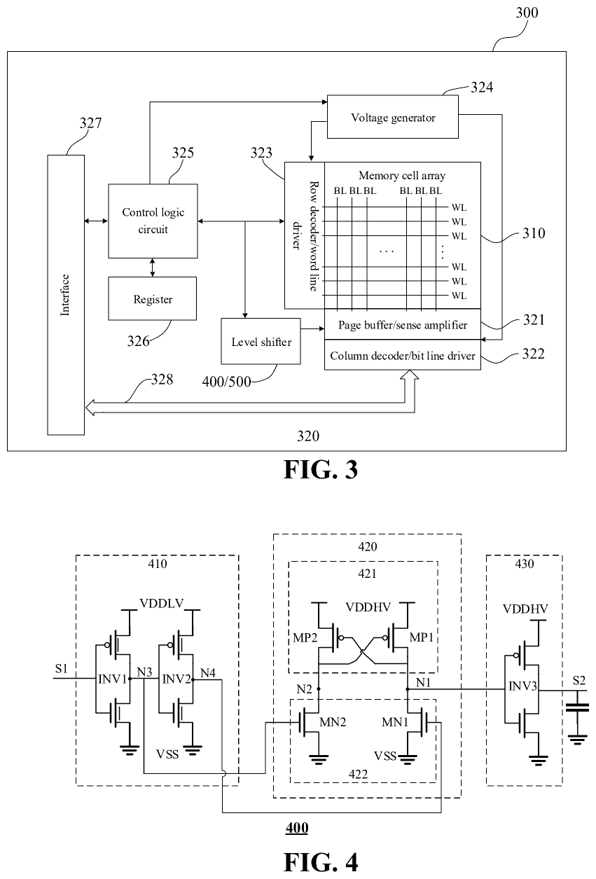

FIG. 3 is a schematic diagram of a memory provided by examples of the present disclosure. As shown in FIG. 3, the memory 300 comprises a memory cell array 310 and a peripheral circuit 320. The memory 300 includes, but is not limited to, a NAND type memory. In an example, the memory cell array 310 may comprise different types of memory cells, such as a Single-Level Cell (SLC), a Multi-Level Cell (MLC), a Trinary-Level Cell (TLC), a Quad-Level Cell (QLC), and a Penta-Level Cell (PLC), etc. The peripheral circuit 320 may be coupled to each memory cell in the memory cell array 310 through a plurality of word lines (WLs) and a plurality of bit lines (BLs). The peripheral circuit 320 may comprise a page buffer (PB) 321, a column decoder/bit line driver 322, a row decoder/word line driver 323, a voltage generator 324, a control logic circuit 325, a register 326, an interface 327, and a data bus 328, etc. In some other examples, the peripheral circuit 320 may further comprise an additional peripheral circuit not shown in FIG. 3.

The voltage generator 324 may generate operation voltages of various levels. For example, in a read operation, the voltage generator 324 may generate, for example, operation voltages of various levels such as a read voltage and a pass voltage, etc. The row decoder/word line driver 323 may be coupled with the control logic circuit 325, the voltage generator 324 and the memory cell array 310. The row decoder 323 may select one selected word line from a plurality of word lines in response to a row address generated by the control logic circuit 325, and provide an operation voltage generated by the voltage generator 324 to the selected word line. The page buffer 321 may be coupled to a memory cell in the memory cell array 310 through a bit line. The page buffer 321 may precharge the bit line by using a respective voltage in response to a page buffer control signal generated by the control logic circuit 325, send and receive data to and from the selected memory cell in a program operation and a read operation, or temporarily store the sent data. The column decoder/bit line driver 322 may send and receive data to and from the page buffer 321, or exchange data with the data bus 328. The interface 327 may send a command and an address received from an external device (e.g., a memory controller) to the control logic circuit 325. The interface 327 may also send the data from the external device to the column decoder 322 through the data bus 328 or output the data from the column decoder 322 to the external device. The control logic circuit 325 may control the peripheral circuit in response to the command and the address. The register 326 may be coupled to the control logic circuit 325 and comprise a state register, a command register, and an address register for storing state information, a command operation code (OP code), and a command address for controlling the operations of each peripheral circuit.

The peripheral circuit 320 may further comprise a level shifter 400. The level shifter 400 may be coupled between the control logic circuit 325 and the page buffer 321, and voltage domains of the control logic circuit 325 and the page buffer 321 are different. In an example, a maximum voltage level of a signal in the control logic circuit 325 may be less than a maximum voltage level of a signal in the page buffer 321, i.e., a power supply voltage provided by the memory to the control logic circuit 325 may be less than a power supply voltage provided to the page buffer 321, such that the control logic circuit 325 has lower power consumption, and meanwhile, the page buffer 321 may apply a sufficiently large bias voltage to a respective bit line, to perform an operation, such as program inhibition and the like, on the bit line. As such, the level shifter 400 may shift a first level signal S1 output by the control logic circuit 325 to a second level signal S2 having a higher voltage level. A voltage level of the second level signal S2 matches a voltage domain of the page buffer 321, and therefore, the page buffer 321 may apply the bias voltage to a respective bit line in response to the second level signal S2. In some other examples, the level shifter may be also coupled between any two circuits/modules in different voltage domains.

FIG. 4 shows a schematic diagram of an example level shifter 400. The level shifter 400 may comprise an input circuit 410, a shifter 420, and an output circuit 430. The input circuit 410 may be coupled to a second power supply terminal, and the shifter 420 and the output circuit 430 may be coupled to a first power supply terminal, wherein a power supply voltage VDDHV of the first power supply terminal is higher than a power supply voltage VDDLV of the second power supply terminal. It may be understood that the power supply voltage of the control logic circuit and the input circuit 410 is VDDLV, i.e., the control logic circuit and the input circuit 410 are in the same voltage domain.

In an example, the input circuit 410 may comprise a first phase inverter INV1 and a second phase inverter INV2 connected in series. The shifter 420 may comprise a feedback circuit 421 and a pull-down circuit 422. The feedback circuit 421 comprises a first transistor MP1 coupled between the first power supply terminal and a first node N1, and a second transistor MP2 coupled between the first power supply terminal and a second node N2. A control terminal of the first transistor MP1 is coupled to the second node N2, and a control terminal of the second transistor MP2 is coupled to the first node N1. The pull-down circuit 422 comprises a third transistor MN1 coupled between the first node N1 and a ground terminal, and a fourth transistor MN2 coupled between the second node N2 and the ground terminal. A control terminal of the third transistor MN1 is coupled to a second output terminal N4 of the second phase inverter INV2, and a control terminal of the fourth transistor MN2 is coupled to a first output terminal N3 of the first phase inverter INV1. The output circuit 430 may comprise a third phase inverter INV3. An input terminal of the third phase inverter INV3 is coupled to the first node N1. In an example, the first transistor MP1 and the second transistor MP2 are P-channel Metal-Oxide-Semiconductor (PMOS) transistors, and the third transistor MN1 and the fourth transistor MN2 are N-channel Metal-Oxide-Semiconductor (NMOS) transistors. It is to be noted that in the level shifter provided by the present disclosure, the type of each transistor may be set according to actual requirements and is not limited to the examples shown in the figures. In an example, the first transistor and the second transistor may be NMOS transistors, and the third transistor and the fourth transistor may be PMOS transistors.

In the case where a signal received by the first phase inverter INV1 is at a low level VSS, the level of the first output terminal N3 of the first phase inverter INV1 is VDDLV, and the fourth transistor MN2 is turned on, such that the level of the second node N2 is pulled down to VSS; and the first transistor MP1 is turned on, such that the level of the first node N1 is pulled up to VDDHV. The level of the second output terminal N4 of the second phase inverter INV2 is VSS, and the third transistor MN1 is turned off, such that the first node N1 is disconnected from the ground terminal.

In the case where the first phase inverter INV1 receives the first level signal S1 (the voltage level is VDDLV), the level of the first output terminal N3 of the first phase inverter INV1 is VSS, and the fourth transistor MN2 is turned off, such that the second node N2 is disconnected from the ground terminal. The level of the second output terminal N4 of the second phase inverter INV2 is VDDLV, and the third transistor MN1 is turned on, such that the level of the first node N1 is discharged from the previous VDDHV until it becomes VSS; the second transistor MP2 is turned on, and the level of the second node N2 is pulled up to VDDHV, such that the first transistor MP1 is turned off, the first node N1 is disconnected from the first power supply terminal, and the level of the first node N1 is kept at VSS. As such, the third phase inverter INV3 of the output circuit 430 may output the second level signal S2 having a higher voltage level (the voltage level is VDDHV), such that the page buffer may apply the bias voltage to a respective bit line in response to the second level signal S2, to perform an operation, such as program inhibition and the like, on the bit line.

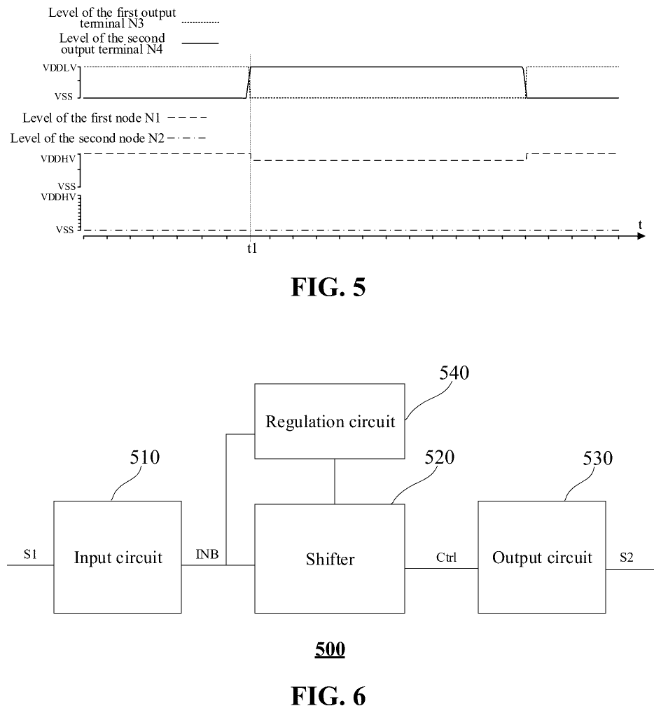

It is to be noted that since the input circuit 410 is coupled to the second power supply terminal, the shifter 420 is coupled to the first power supply terminal, and the power supply voltage VDDHV of the first power supply terminal is higher than the power supply voltage VDDLV of the second power supply terminal, manufacturing processes of the transistor in the input circuit 410 and the transistor in the shifter 420 are different, and their threshold voltages are also different. In an example, the NMOS in the shifter 420 adopts a slow process corner, and the threshold voltage of the NMOS transistor in the shifter 420 will be higher than the threshold voltage of the NMOS transistor in the input circuit 410. In some examples, if the level shifter 400 works under extreme conditions (e.g., in a low temperature environment), the threshold voltage of the NMOS transistor in the shifter 420 will further rise. For example, the threshold voltage of the third transistor MN1 rises to be higher than the power supply voltage VDDLV of the second power supply terminal. As such, with reference to the timing diagram of each node level of the level shifter under the extreme conditions shown in FIG. 5, at a time instant t1, the first phase inverter INV1 receives the first level signal S1 (the voltage level is VDDLV), and the level of the second output terminal N4 of the second phase inverter INV2 is inverted from VSS to VDDLV. However, the level VDDLV of the node N4 cannot turn on the third transistor MN1. The first node N1 cannot be discharged normally or is discharged incompletely, and the level of the first node N1 still remains at VDDHV or is slightly lower than VDDHV. The second transistor MP2 cannot be turned on, and the level of the second node N2 still remains at VSS. Therefore, the first transistor MP1 still remains turned on, such that the level of the first node N1 further remain at VDDHV or be slightly lower than VDDHV. That is to say, although the input circuit 410 receives the first level signal S1 (the voltage level is VDDLV), the level of the first node N1 cannot be inverted from VDDHV to VSS. As a result, the third phase inverter INV3 of the output circuit 430 cannot normally output the second level signal S2 having the level of VDDHV, and the control logic circuit in the peripheral circuit cannot control the page buffer to perform operations on a respective bit line, resulting in a degradation in performance and reliability of the memory.

In some examples, the third transistor MN1 (and the fourth transistor MN2) in the shifter 420 may be replaced with a transistor having a lower threshold voltage, such that the level VDDLV of the node N4 may also turn on the third transistor MN1 even under the extreme conditions, i.e., the first node N1 may be discharged normally from VDDHV to VSS, thereby ensuring that the third phase inverter INV3 of the output circuit 430 may normally output the second level signal S2 having the level of VDDHV. However, disposing a transistor having a lower threshold voltage (e.g., the third transistor MN1) in a circuit (e.g., the shifter 420) in a higher voltage domain may increase the complexity and cost of the manufacturing process.

As shown in FIG. 6, the present disclosure provides a level shifter 500, comprising: an input circuit 510, a shifter 520 and an output circuit 530 that are coupled sequentially, wherein the input circuit 510 is configured to generate a first input signal INB in response to a first level signal S1; and a regulation circuit 540 coupled to the input circuit 510 and the shifter 520 separately, wherein the regulation circuit 540 is configured to regulate a first control signal Ctrl output by the shifter 520 in response to the first input signal INB, wherein a voltage domain of the shifter 520 is different from a voltage domain of the input circuit 510; and the output circuit 530 is configured to output a second level signal S2 in response to the regulated first control signal Ctrl, wherein a voltage level of the second level signal S2 is higher than a voltage level of the first level signal S1.

In examples of the present disclosure, the level shifter 500 may be applied to any electronic apparatus containing a digital circuit, such as a memory, a processor, a controller, a programmable logic device, and the like. The level shifter 500 comprises the input circuit 510, the shifter 520 and the output circuit 530 that are coupled sequentially, and the regulation circuit 540 coupled between the input circuit 510 and the shifter 520.

The input circuit 510 may receive the first level signal S1 and generate the first input signal INB in response to the first level signal S1. The first level signal S1 may be a signal generated by a circuit in a lower voltage domain. That is to say, the circuit generating the first level signal S1 may have lower power consumption and be configured to control other circuits in a higher voltage domain. In an example, the input circuit 510 may comprise one or more phase inverters for generating one or more input signals. The first input signal INB may have an inverted phase to the first level signal S1. The input circuit 510 and the circuit generating the first level signal S1 may be in the same voltage domain.

The shifter 520 may output the first control signal Ctrl in response to the input signal (including, but not limited to, the first input signal INB) generated by the input circuit 510. In an example, the shifter 520 may comprise a cross pair circuit, a pull-down circuit, and the like. With reference to the above examples, since the voltage domain of the shifter 520 is different from the voltage domain of the input circuit 510, and under the extreme conditions, the input signal generated by the input circuit 510 may be unable to turn on/off the respective transistor in the shifter 520, the shifter 520 cannot output the first control signal Ctrl having a correct level. As a result, the output circuit 530 fails to normally output the second level signal S2. In an example, the output circuit 530 may comprise one or more phase inverters.

The regulation circuit 540 may regulate the level of the first control signal Ctrl output by the shifter 520 in response to the first input signal INB generated by the input circuit 510, such that the output circuit 530 may output the second level signal S2. The voltage level of the second level signal S2 is higher than the voltage level of the first level signal S1. The regulation circuit 540 may comprise components such as a transistor having a lower threshold voltage (under the extreme conditions, its threshold voltage is lower than the power supply voltage coupled to the input circuit), a capacitor, and the like. In an example, under the extreme conditions, the input signal generated by the input circuit 510 cannot turn on/off a respective transistor in the shifter 520, and the regulation circuit 540 may regulate the level of the first control signal Ctrl output by the shifter 520 by charging or discharging the output node of the shifter 520, i.e., the level of the output node of the shifter 520 may be inverted normally. As such, the output circuit 530 may output the second level signal S2 in response to the regulated first control signal Ctrl. It may be understood that the voltage domains of the output circuit 530 and the shifter 520 may be the same.

In some examples, the first level signal S1 may be generated by the control logic circuit in the peripheral circuit of the memory. The first level signal S1 generated by the control logic circuit may be shifted to the second level signal S2 having a higher voltage level via the level shifter 500, and the page buffer in the peripheral circuit may perform various operations on the bit line in response to the second level signal S2. It is to be noted that the level shifter 500 may be also coupled between any two circuits/modules in different voltage domains.

In the examples of the present disclosure, the voltage domain of the shifter 520 is different from the voltage domain of the input circuit 510, and the regulation circuit 540 is configured to regulate the first control signal Ctrl output by the shifter 520 in response to the first input signal INB. The output circuit 530 is configured to output the second level signal S2 in response to the regulated first control signal Ctrl. As such, in case of a large voltage difference between a voltage at the power supply terminal coupled to the shifter 520 and a voltage at the power supply terminal coupled to the input circuit 510, the regulation circuit 540 may regulate the level of the first control signal Ctrl, such that the level of the first control signal Ctrl output by the shifter 520 may be inverted normally, thereby ensuring that the output circuit 530 may normally output the second level signal S2 having a higher voltage level, so as to improve the reliability of the level shifter.

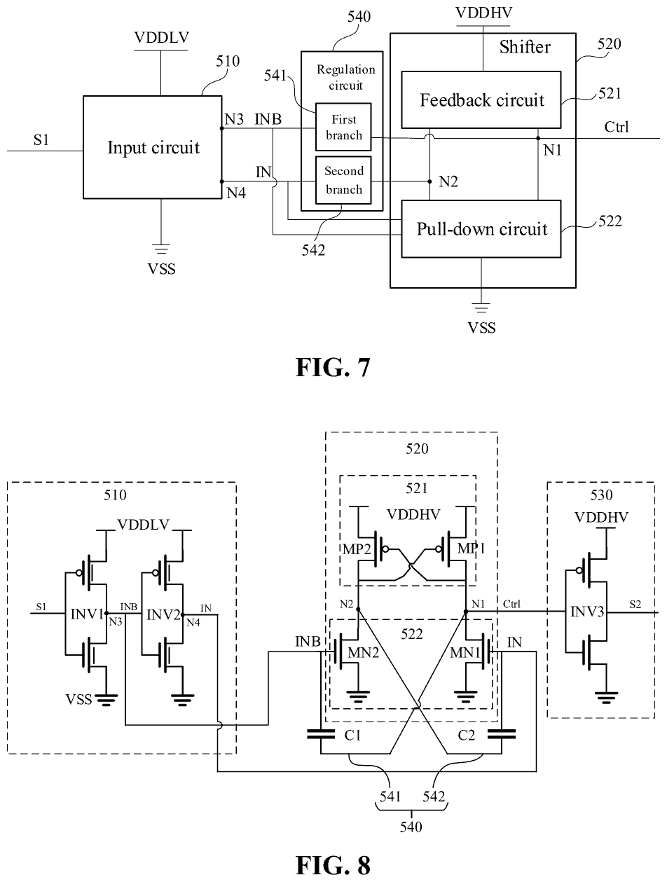

In some examples, as shown in FIG. 7, the input circuit 510 is configured to generate the first input signal INB with an inverted phase to the first level signal S1 in response to the first level signal S1, wherein the first output terminal N3 of the input circuit 510 is configured to output the first input signal INB. The shifter 520 comprises a feedback circuit 521 that is coupled to a first power supply terminal and a first node N1 of the shifter 520 separately, wherein the feedback circuit 521 is configured to provide a power supply voltage level of the first power supply terminal to the first node N1. The regulation circuit 540 comprises a first branch 541 that is coupled to the first node N1 and the first output terminal N3 of the input circuit 510, wherein the first branch 541 is configured to discharge the first node N1 in response to the first input signal INB, so as to regulate the first control signal Ctrl output by the shifter 520.

In the examples of the present disclosure, the input circuit 510 may comprise at least one phase inverter, and the first output terminal N3 of the input circuit 510 is configured to output the first input signal INB with an inverted phase to the first level signal S1.

The shifter 520 may comprise the feedback circuit 521 coupled between the first power supply terminal and the first node N1. Here, the power supply voltage of the first power supply terminal is different from the power supply voltage of the second power supply terminal coupled to the input circuit 510, i.e., the voltage domain of the shifter 520 is different from the voltage domain of the input circuit 510. In an example, the power supply voltage level VDDHV of the first power supply terminal is higher than the power supply voltage level VDDLV of the second power supply terminal. The feedback circuit 521 may be configured to provide the power supply voltage level VDDHV of the first power supply terminal to the first node N1, or disconnect the first node N1 from the first power supply terminal, and the feedback circuit 521 may comprise a cross pair circuit. In an example, in the case where the level of the signal received by the input circuit 510 is VSS, the feedback circuit 521 may enable a connection between the first node N1 and the first power supply terminal, and the level of the first node N1 is pulled up to VDDHV. In the case where the input circuit 510 receives the first level signal S1 (the level is VDDLV), the level of the first input signal INB generated by the input circuit 510 is VSS, and the first branch 541 of the regulation circuit 540 may discharge the first node N1 in response to the first input signal INB having the level of VSS, such that the level of the first node N1 drops from VDDHV to a suitable voltage level (e.g., a voltage level that can change the on state of a respective transistor in the output circuit). That is to say, the first branch 541 may regulate the level of the first control signal Ctrl output by the shifter 520 in response to the first input signal INB, such that the level of the first control signal Ctrl may be inverted normally, thereby ensuring that the output circuit 530 may normally output the second level signal S2 having a higher voltage level, so as to improve the reliability of the level shifter. The first branch 541 may comprise components such as a transistor having a lower threshold voltage (under the extreme conditions, its threshold voltage is lower than the power supply voltage coupled to the input circuit), a capacitor, and the like.

In some examples, as shown in FIG. 7, the input circuit 510 is further configured to generate a second input signal IN with an inverted phase to the first input signal INB in response to the first input signal INB, wherein a second output terminal N4 of the input circuit 510 is configured to output the second input signal IN. The regulation circuit 540 further comprise a second branch 542 that is coupled to a second node N2 of the shifter 520 and the second output terminal N4 of the input circuit, wherein the second branch 542 is configured to regulate the level of the second node N2 in response to the second input signal IN, such that the feedback circuit 521 stops providing the power supply voltage level to the first node N1. The feedback circuit 521 is coupled to the first power supply terminal and the second node N2 separately.

In the examples of the present disclosure, the input circuit 510 may comprise at least one phase inverter, the first output terminal N3 of the input circuit 510 is configured to output the first input signal INB with an inverted phase to the first level signal S1, and the second output terminal N4 of the input circuit 510 is configured to output the second input signal IN with an inverted phase to the first input signal INB.

The feedback circuit 521 may be further coupled to the first power supply terminal and the second node N2. The feedback circuit 521 may be configured to provide the power supply voltage level VDDHV of the first power supply terminal to the second node N2, or disconnect the second node N2 from the first power supply terminal, and the feedback circuit 521 may comprise a cross pair circuit. In an example, in the case where the level of the signal received by the input circuit 510 is VSS, the feedback circuit 521 may disconnect the second node N2 from the first power supply terminal, such that the level of the second node N2 is pulled down to VSS. In the case where the input circuit 510 receives the first level signal S1 (the level is VDDLV), the level of the second input signal IN generated by the input circuit 510 is VDDLV, and the second branch 542 of the regulation circuit 540 may regulate the level of the second node N2 (e.g., increase the level of the second node N2) in response to the second input signal IN having the level of VDDLV. Thus, the feedback circuit 521 disconnects the first node N1 from the first power supply terminal in response to the regulated voltage level of the second node N2, facilitating discharge of the first node N1. That is to say, the second branch 542 may indirectly facilitate the discharge of the first node N1 in response to the second input signal IN, such that the level of the first control signal Ctrl may be inverted normally, thereby ensuring that the output circuit 530 may normally output the second level signal S2 having a higher voltage level, so as to improve the reliability of the level shifter. The second branch 542 may comprise components, such as a transistor having a lower threshold voltage (under the extreme conditions, its threshold voltage is lower than the power supply voltage coupled to the input circuit), a capacitor, and the like.

In some examples, the second branch 542 is configured to charge the second node N2 in response to the second input signal IN until the first node N1 is disconnected from the first power supply terminal.

In the examples of the present disclosure, the second branch 542 of the regulation circuit 540 may charge the second node N2 in response to the second input signal IN, such that the voltage level of the second node N2 rises from VSS to be higher than a threshold voltage of a transistor in the feedback circuit 521. Thus, the feedback circuit 521 disconnects the first node N1 from the first power supply terminal in response to the risen voltage level of the second node N2, so as to further facilitate the discharge of the first node N1, such that the level of the first control signal Ctrl may be inverted normally, ensuring that the output circuit 530 may normally output the second level signal S2 having a higher voltage level, so as to improve the reliability of the level shifter.

In some examples, as shown in FIG. 8, the feedback circuit 521 comprises: a first transistor MP1, wherein a first terminal of the first transistor MP1 is coupled to the first power supply terminal, a second terminal of the first transistor MP1 is coupled to the first node N1, and a control terminal of the first transistor MP1 is coupled to the second node N2; and a second transistor MP2, wherein a first terminal of the second transistor MP2 is coupled to the first power supply terminal, a second terminal of the second transistor MP2 is coupled to the second node N2, and a control terminal of the second transistor MP2 is coupled to the first node N1.

In the examples of the present disclosure, the feedback circuit 521 may be a cross pair circuit. The feedback circuit 521 comprises a positive feedback structure constituted by the first transistor MP1 and the second transistor MP2. In an example, the first terminal and the second terminal of the first transistor MP1 are coupled to the first power supply terminal and the first node N1 respectively, and the control terminal of the first transistor MP1 is coupled to the second node N2. The first terminal and the second terminal of the second transistor MP2 are coupled to the first power supply terminal and the second node N2 respectively, and the control terminal of the second transistor MP2 is coupled to the first node N1. Here, both the first transistor MP1 and the second transistor MP2 as being PMOS transistors are illustrated as an example for a positive feedback process of the feedback circuit 521. When the level of the second node N2 is VSS, the first transistor MP1 is turned on, and the first node N1 is connected with the first power supply terminal, such that the level of the first node N1 is pulled up to VDDHV, thereby turning off the second transistor MP2 and keeping the second node N2 at VSS. When the level of the first node N1 is VSS, the second transistor MP2 is turned on, and the second node N2 is connected with the first power supply terminal, such that the level of the second node N2 is pulled up to VDDHV, thereby turning off the first transistor MP1 and keeping the first node N1 at VSS. It may be understood that first transistor and the second transistor may be also NMOS transistors, and in that case, the first transistor may be coupled between the ground terminal and the first node, and the control terminal of the first transistor may be coupled to the second node; the second transistor may be coupled between the ground terminal and the second node, and the control terminal of the second transistor may be coupled to the first node.

In some examples, as shown in FIG. 8, the shifter 520 further comprises a pull-down circuit 522. The pull-down circuit 522 comprises: a third transistor MN1, wherein a first terminal of the third transistor MN1 is coupled to the first node N1, a second terminal of the third transistor MN1 is coupled to the ground terminal, and a control terminal of the third transistor MN1 is coupled to the second output terminal N4 of the input circuit 510; and a fourth transistor MN2, wherein a first terminal of the fourth transistor MN2 is coupled to the second node N2, a second terminal of the fourth transistor MN2 is coupled to the ground terminal, and a control terminal of the fourth transistor MN2 is coupled to the first output terminal N3 of the input circuit 510.

In the examples of the present disclosure, the shifter 520 may further comprise the pull-down circuit 522. The pull-down circuit 522 comprises the third transistor MN1 and the fourth transistor MN2. In an example, the first terminal and the second terminal of the third transistor MN1 may be coupled to the first node N1 and the ground terminal respectively, and the control terminal of the third transistor MN1 is coupled to the second output terminal N4 of the input circuit 510. The first terminal and the second terminal of the fourth transistor MN2 are coupled to the second node N2 and the ground terminal respectively, and the control terminal of the fourth transistor MN2 is coupled to the first output terminal N3 of the input circuit 510.

As such, in the case where a signal received by the input circuit 510 is at a low level VSS, the level of the first output terminal N3 is VDDLV and the fourth transistor MN2 is turned on, such that the level of the second node N2 is pulled down to VSS; and the first transistor MP1 is turned on, such that the level of the first node N1 is pulled up to VDDHV. The level of the second output terminal N4 is VSS, and the third transistor MN1 is turned off, such that the first node N1 is disconnected from the ground terminal. In the case where the input circuit 510 receives the first level signal S1 (the voltage level is VDDLV), the first output terminal N3 outputs the first input signal INB having the level of VSS, and the fourth transistor MN2 is turned off, such that the second node N2 is disconnected from the ground terminal. The second output terminal N4 outputs the second input signal IN having the level of VDDLV, and the third transistor MN1 is turned on, such that the level of the first node N1 is discharged from the previous VDDHV until it becomes VSS; the second transistor MP2 is turned on, such that the level of the second node N2 is pulled up to VDDHV, thereby turning off the first transistor MP1, disconnecting the first node N1 from the first power supply terminal and keeping the level of the first node N1 at VSS. As such, the output circuit 530 may output the second level signal S2 (the voltage level is VDDHV) having a higher voltage level, so as to improve the reliability of the level shifter.

In some examples, the threshold voltage of the third transistor MN1 is higher than the voltage level of the second input signal IN.

In the examples of the present disclosure, if the level shifter works under extreme conditions (e.g., in a low temperature environment), the threshold voltage of the transistor in the shifter 520 will further rise. For example, the threshold voltage of the third transistor MN1 rises to be higher than the voltage level of the second input signal IN (e.g., higher than the power supply voltage VDDLV of the second power supply terminal). As such, the second input signal IN having the level of VDDLV cannot turn on the third transistor MN1, and the first node N1 remains disconnected from the ground terminal. In this case, the first branch 541 may discharge the first node N1 in response to the first input signal INB having the level of VSS, such that the level of the first node N1 drops from VDDHV to a suitable voltage level (e.g., a voltage level that can change the on state of a respective transistor in the output circuit), i.e., the level of the first control signal Ctrl output by the shifter 520 may be inverted normally. The second branch 542 may charge the second node N2 in response to the second input signal IN having the level of VDDLV, such that the voltage level of the second node N2 rises from VSS to be higher than the threshold voltage of the first transistor MP1. The first transistor MP1 is turned off, and the first node N1 is disconnected from the first power supply terminal to further facilitate discharge of the first node N1, such that the level of the first control signal Ctrl may be inverted normally, thereby ensuring that the output circuit 530 may normally output the second level signal S2 having a higher voltage level, so as to improve the reliability of the level shifter.

In some examples, as shown in FIG. 8, the first branch 541 comprises a first capacitor C1; and the second branch 542 comprises a second capacitor C2.

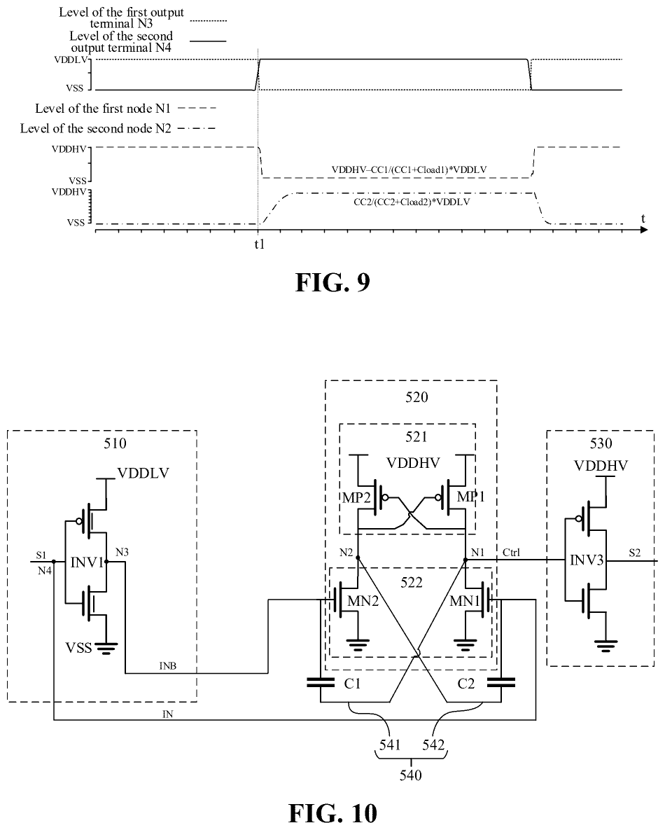

In the examples of the present disclosure, the first branch 541 may comprise the first capacitor C1 to discharge the first node N1 according to the coupling effect; and the second branch 542 may comprise the second capacitor C2 to charge the second node N2 according to the coupling effect. In an example, if the level of the signal initially received by the input circuit 510 is VSS, the level of the first node N1 is VDDHV and the level of the second node N2 is VSS. Next, under the extreme conditions (e.g., in the low temperature environment), the input circuit 510 receives the first level signal S1 (the level is VDDLV), the second input signal IN having the level of VDDLV cannot turn on the third transistor MN1, and the first node N1 remains disconnected from the ground terminal. In this case, with reference to the timing diagram shown in FIG. 9, at a time instant t1, the level of the first input signal INB is inverted from VDDLV to VSS, i.e., the level of the first output terminal N3 is changed from VDDLV to VSS. The first node N1 is coupled to the first output terminal N3 through the first capacitor C1, and the level of the first node N1 is discharged from VDDHV to VDDHV−CC1/(CC1+Cload1)*VDDLV, such that the level of the first control signal Ctrl may be inverted normally, wherein Cload1 represents a capacitance value at the first output terminal N3 of in input circuit 510, and CC1 represents a capacitance value of the first capacitor C1. The level of the second input signal IN is inverted from VSS to VDDLV, i.e., the level of the second output terminal N4 is changed from VSS to VDDLV. The second node N2 is coupled to the second output terminal N4 through the second capacitor C2, the level of the second node N2 is charged from VSS to CC2/(CC2+Cload2)*VDDLV, the first transistor MP1 is turned off, and the first node N1 is disconnected from the first power supply terminal, thereby indirectly facilitating the discharge of the first node N1, wherein Cload2 represents a capacitance value at the second output terminal N4 in the input circuit 510, and CC2 represents a capacitance value of the second capacitor C2.

In some examples, the level shifter 500 is located in the peripheral circuit of the memory. In this case, the first capacitor C1 and the second capacitor C2 may be formed by a metal-oxide semiconductor field effect transistor (MOSFET) process, a metal process and the like, thereby improving compatibility with the semiconductor process and saving the manufacturing cost.

In some examples, as shown in FIG. 8, the third transistor MN1 and the fourth transistor MN2 are NMOS transistors; and the input circuit 510 comprises at least one NMOS transistor, wherein the threshold voltage of the third transistor MN1 and the threshold voltage of the fourth transistor MN2 are both the same as the threshold voltage of the NMOS transistor in the input circuit 510.

In the examples of the present disclosure, the input circuit 510 may comprise at least one NMOS transistor, such as the NMOS transistors in the first phase inverter INV1 and the second phase inverter INV2. It may be understood that since the input circuit 510 is coupled to the second power supply terminal having the power supply voltage of VDDLV, the shifter 520 is coupled to the first power supply terminal having the power supply voltage of VDDHV, and VDDHV is higher than VDDLV, if the third transistor MN1 and the fourth transistor MN2 are formed by a manufacturing process for a transistor in a high voltage circuit, the threshold voltages of the third transistor MN1 and the fourth transistor MN2 are high. Under the extreme conditions, the threshold voltages of the third transistor MN1 and the fourth transistor MN2 further rise, thereby resulting in the input signal (including, but not limited to, the first input signal INB and the second input signal IN) generated by the input circuit 510 failing to turn on at least one of the third transistor MN1 or the fourth transistor MN2 and the first control signal Ctrl output by the shifter 520 being unable to be inverted normally. Therefore, the threshold voltages of the third transistor MN1 and the fourth transistor MN2 may be the same as the threshold voltage of the NMOS transistor in the input circuit 510, i.e., both the third transistor MN1 and the fourth transistor MN2 are transistors having lower threshold voltages, thereby avoiding that the input signal generated by the input circuit 510 cannot control at least one of the third transistor MN1 or the fourth transistor MN2. In an example, the third transistor MN1 and the fourth transistor MN2 may be formed using a manufacturing process for a transistor in a low voltage circuit. For example, the third transistor MN1 and the fourth transistor MN2 may be formed using the same process as the NMOS transistor in the input circuit 510. It is to be noted that, on the basis that the first branch 541 and the second branch 542 are used to ensure that the first control signal Ctrl may be inverted normally, the third transistor MN1 and the fourth transistor MN2 may be provided as transistors having the same threshold voltages as the NMOS transistor in the input circuit 510, thereby further improving the reliability of the level shifter.

In some examples, the input circuit comprises at least one phase inverter.

In the examples of the present disclosure, as shown in FIG. 8, the input circuit 510 may comprise two phase inverters, and the first output terminal N3 and the second output terminal N4 of the input circuit 510 may serve as the output terminals of the first phase inverter INV1 and the second phase inverter INV2 respectively. As shown in FIG. 10, the input circuit 510 may comprise one phase inverter, and the first output terminal N3 and the second output terminal N4 of the input circuit 510 may serve as the output terminal and the input terminal of the first phase inverter INV1 respectively. It may be understood that the input circuit 510 may further comprise two or more phase inverters, as long as the level of the first input signal INB output by the first output terminal N3 has an inverted phase to the level of the first level signal S1, and the level of the second input signal IN output by the second output terminal N4 is the same as the level of the first level signal S1, which is not limited here. The fewer phase inverters in the input circuit 510, the more advantageous it is to reduce the signal delay of the level shifter; and the more phase inverters in the input circuit 510, the more advantageous it is to rectify a signal pulse and improve the signal quality.

The present disclosure provides a memory comprising a page buffer, a control logic circuit, and a level shifter. The level shifter is coupled between the control logic circuit and the page buffer. The level shifter comprises: a first phase inverter and a second phase inverter connected sequentially in series, wherein the first phase inverter is configured to generate a first input signal in response to a first level signal output by the control logic circuit; a first transistor, wherein a first terminal of the first transistor is coupled to a first power supply terminal, a second terminal of the first transistor is coupled to a first node, a control terminal of the first transistor is coupled to a second node, and a voltage of a second power supply terminal coupled to the first phase inverter is different from a voltage of the first power supply terminal; a second transistor, wherein a first terminal of the second transistor is coupled to the first power supply terminal, a second terminal of the second transistor is coupled to the second node, and a control terminal of the second transistor is coupled to the first node; a first capacitor coupled to the first node and an output terminal of the first phase inverter, wherein the first capacitor is configured to regulate a first control signal output by the first node in response to the first input signal; a second capacitor coupled to the second node and an output terminal of the second phase inverter; and a third phase inverter coupled to the first node, wherein the third phase inverter is configured to output a second level signal in response to the regulated first control signal, wherein a voltage level of the second level signal is higher than a voltage level of the first level signal.

In the examples of the present disclosure, with reference to FIG. 3, the memory 300 comprises a memory cell array 310 and a peripheral circuit 320. The peripheral circuit 320 comprises the control logic circuit 325, the page buffer 321, and the level shifter 500 coupled between the control logic circuit 325 and the page buffer 321. The page buffer 321 may precharge a bit line in response to a control signal generated by the control logic circuit 325, send and receive data to and from a selected memory cell in a program operation and a read operation, or temporarily store the sent data. Voltage domains of the control logic circuit 325 and the page buffer 321 are different. In an example, a power supply voltage provided by the memory to the control logic circuit 325 may be less than a power supply voltage provided to the page buffer 321, such that the control logic circuit 325 has lower power consumption, and meanwhile, the page buffer 321 may apply a sufficiently large bias voltage to a respective bit line, to perform an operation, such as program inhibition and the like, on the bit line. The level shifter 500 may shift a first level signal S1 output by the control logic circuit 325 to a second level signal S2 having a higher voltage level. A voltage level of the second level signal S2 matches a voltage domain of the page buffer 321, and therefore, the page buffer 321 may apply the bias voltage to a respective bit line in response to the second level signal S2.

In an example, with reference to FIG. 8, the level shifter 500 comprises the input circuit 510, the shifter 520 and the output circuit 530 that are coupled sequentially, and the regulation circuit 540 coupled between the input circuit 510 and the shifter 520.

The input circuit 510 may receive the first level signal S1 and generate the first input signal INB in response to the first level signal S1. The first level signal S1 may be generated by the control logic circuit. In an example, the input circuit 510 may comprise one or more phase inverters for generating one or more input signals. The first input signal INB may have an inverted phase to the first level signal S1. The input circuit 510 and the control logic circuit may be in the same voltage domain.

The shifter 520 may output the first control signal Ctrl in response to the input signal (including, but not limited to, the first input signal INB) generated by the input circuit 510. In an example, the shifter 520 may comprise a cross pair circuit, a pull-down circuit, and the like. With reference to the above examples, since the voltage domain of the shifter 520 is different from the voltage domain of the input circuit 510, and under the extreme conditions, the input signal generated by the input circuit 510 may be unable to turn on/off the respective transistor in the shifter 520, the shifter 520 cannot output the first control signal Ctrl having a correct level, As a result, the output circuit 530 fails to normally output the second level signal S2. In an example, the output circuit 530 may comprise one or more phase inverters.

The regulation circuit 540 may regulate the level of the first control signal Ctrl output by the shifter 520 in response to the first input signal INB generated by the input circuit 510, such that the output circuit 530 may output the second level signal S2. The voltage level of the second level signal S2 is higher than the voltage level of the first level signal S1. The regulation circuit 540 may comprise components such as a transistor having a lower threshold voltage (under the extreme conditions, its threshold voltage is lower than the power supply voltage coupled to the input circuit), a capacitor, and the like. In an example, under the extreme conditions, the input signal generated by the input circuit 510 cannot turn on/off a respective transistor in the shifter 520, and the regulation circuit 540 may regulate the level of the first control signal Ctrl output by the shifter 520 by charging or discharging the output node of the shifter 520, i.e., the level of the output node of the shifter 520 may be inverted normally. As such, the output circuit 530 may output the second level signal S2 in response to the regulated first control signal Ctrl. It may be understood that the voltage domains of the output circuit 530 and the shifter 520 may be the same.

As such, in case of a large voltage difference between a voltage at the power supply terminal coupled to the shifter 520 and a voltage at the power supply terminal coupled to the input circuit 510, the regulation circuit 540 may regulate the level of the first control signal Ctrl, such that the level of the first control signal Ctrl output by the shifter 520 may be inverted normally, thereby ensuring that the output circuit 530 may normally output the second level signal S2 having a higher voltage level, so as to improve the reliability of the level shifter.

In a further example, the input circuit 510 may comprise the first phase inverter INV1 and the second phase inverter INV2 that are connected in series. The first phase inverter INV1 may generate the first input signal INB in response to the first level signal S1 output by the control logic circuit. The shifter 520 may comprises the feedback circuit 521 and the pull-down circuit 522. The feedback circuit 521 comprises the first transistor MP1 and the second transistor MP2. The first terminal and the second terminal of the first transistor MP1 are coupled to the first power supply terminal and the first node N1 respectively, and the control terminal of the first transistor MP1 is coupled to the second node N2. The first terminal and the second terminal of the second transistor MP2 are coupled to the first power supply terminal and the second node N2 respectively, and the control terminal of the second transistor MP2 is coupled to the first node N1. The voltage VDDLV of the second power supply terminal coupled to the first phase inverter INV1 is different from the voltage VDDHV of the first power supply terminal, for example, the voltage VDDLV of the first power supply terminal is higher than the voltage VDDLV of the second power supply terminal. The regulation circuit 540 comprises the first branch 541 and the second branch 542. The first branch 541 comprises the first capacitor C1 coupled to the first node N1 and the first output terminal N3 of the first phase inverter INV1, and the second branch 542 comprises the second capacitor C2 coupled to the second node N2 and the second output terminal N4 of the second phase inverter INV2. The output circuit 530 comprises the third phase inverter INV3, and the input terminal of the third phase inverter INV3 is coupled to the first node N1. The third phase inverter INV3 may output the second level signal S2 in response to the regulated first control signal Ctrl.

The first capacitor C1 may discharge the first node N1 according to the coupling effect; and the second capacitor C2 may charge the second node N2 according to the coupling effect. In an example, if the level of the signal initially received by the input circuit 510 is VSS, the level of the first node N1 is VDDHV and the level of the second node N2 is VSS. Next, under the extreme conditions (e.g., in the low temperature environment), the input circuit 510 receives the first level signal S1 (the level is VDDLV), and the second input signal IN having the level of VDDLV cannot turn on the third transistor MN1, and the first node N1 remains disconnected from the ground terminal. In this case, with reference to the timing diagram shown in FIG. 9, at a time instant t1, the level of the first input signal INB is inverted from VDDLV to VSS, i.e., the level of the first output terminal N3 is changed from VDDLV to VSS. The first node N1 is coupled to the first output terminal N3 through the first capacitor C1, and the level of the first node N1 is discharged from VDDHV to VDDHV−CC1/(CC1+Cload1)*VDDLV, such that the level of the first control signal Ctrl may be inverted normally, wherein Cload1 represents a capacitance value at the first output terminal N3 of in input circuit 510, and CC1 represents a capacitance value of the first capacitor C1. The level of the second input signal IN is inverted from VSS to VDDLV, i.e., the level of the second output terminal N4 is changed from VSS to VDDLV. The second node N2 is coupled to the second output terminal N4 through the second capacitor C2, the level of the second node N2 is charged from VSS to CC2/(CC2+Cload2)*VDDLV, the first transistor MP1 is turned off, and the first node N1 is disconnected from the first power supply terminal, thereby indirectly facilitating the discharge of the first node N1, wherein Cload2 represents a capacitance value at the second output terminal N4 in the input circuit 510, and CC2 represents a capacitance value of the second capacitor C2.

It may be understood that in the case where the shifter 520 receives the second input signal IN (the level is VDDLV) having a lower voltage level, the first capacitor C1 and the second capacitor C2 may still ensure that the level of the first control signal Ctrl may be inverted normally. That is to say, the power supply voltage of the second power supply terminal coupled to the control logic circuit and the input circuit may be further reduced, i.e., VDDLV may be lower. Thus, the energy consumption of the control logic circuit and the input circuit is reduced.

In some examples, the second phase inverter is configured to generate the second input signal in response to the first input signal; and the second capacitor is configured to regulate the level of the second node in response to the second input signal, so as to turn off the first transistor.

In some examples, the first capacitor is configured to discharge the first node in response to the first input signal, so as to regulate the first control signal output by the first node; and the second capacitor is configured to charge the second node in response to the second input signal until the first transistor is turned off.

In some examples, the level shifter further comprises: the third transistor, wherein the first terminal of the third transistor is coupled to the first node, the second terminal of the third transistor is coupled to the ground terminal, and the control terminal of the third transistor is coupled to the output terminal of the second phase inverter; and the fourth transistor, wherein the first terminal of the fourth transistor is coupled to the second node, the second terminal of the fourth transistor is coupled to the ground terminal, and the control terminal of the fourth transistor is coupled to the output terminal of the first phase inverter.

In some examples, the first transistor and the second transistor are PMOS transistors, and the third transistor and the fourth transistor are NMOS transistors.

In some examples, a threshold voltage of the third transistor is higher than a voltage level of the second input signal.

In some examples, the third transistor and the fourth transistor are NMOS transistors; and a threshold voltage of the third transistor, a threshold voltage of the fourth transistor, a threshold voltage of an NMOS transistor in the first phase inverter and a threshold voltage of an NMOS transistor in the second phase inverter are all the same.

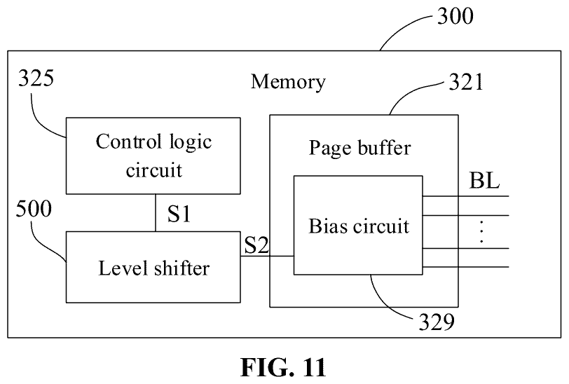

In some examples, as shown in FIG. 11, the page buffer 321 comprises a bias circuit 329; the level shifter 500 is coupled between the bias circuit 329 and the control logic circuit 325; and the bias circuit 329 is configured to apply the bias voltage to a bit line in response to the second level signal S2.

In the examples of the present disclosure, the voltage domains of the control logic circuit 325 and the page buffer 321 are different, and the maximum voltage level of the signal in the control logic circuit 325 may be less than the maximum voltage level of the signal in the page buffer 321, i.e., the power supply voltage provided by the memory to the control logic circuit 325 may be lower than the power supply voltage provided to the page buffer 321. As such, the level shifter 500 may shift the first level signal S1 output by the control logic circuit 325 to the second level signal S2 having a higher voltage level. The level of the second level signal S2 matches the voltage domain of the page buffer 321, and therefore, the bias circuit 329 in the page buffer 321 may apply the bias voltage to a respective bit line in response to the second level signal S2, to perform an operation, such as program inhibition and the like, on the bit line.

The present disclosure provides a memory system, comprising the memory of any of the above examples, and a memory controller coupled to the memory.

In the examples of the present disclosure, the memory system may correspond to the memory system 102 in the examples shown in FIG. 1; the memory may correspond to the memory 104 in the examples shown in FIG. 1 and the memory 300 in the examples shown in FIG. 3, and the memory controller may correspond to the memory controller 106 in the examples shown in FIG. 1. The memory controller is configured to control the memory. The specific functions and applications of and interactive operations between the memory and the memory controller are no longer repeated here.

The present disclosure provides an electronic apparatus, comprising the memory system described in the above examples.

In the examples of the present disclosure, the electronic apparatus may be understood by correspondingly referring to the electronic apparatus 100 in the examples shown in FIG. 1, which will no longer be repeated here. The electronic apparatus may be implemented by the memory system in the above examples, and one or more of Application Specific Integrated Circuit (ASIC), DSP, Programmable Logic Device (PLD), Complex Programmable Logic Device (CPLD), Field-Programmable Gate Array (FPGA), general-purpose processor, controller, Micro Controller Unit (MCU), microprocessor, or other electronic elements.

In the level shifter, the memory, the memory system, and the electronic apparatus provided by the present disclosure, the regulation circuit may regulate the level of the first control signal, such that the level of the first control signal output by the shifter may be inverted normally, thereby ensuring that the output circuit may normally output the second level signal having a higher voltage level, so as to improve the reliability of the level shifter. In a further example, the regulation circuit may comprise the first branch and the second branch. The first branch comprises the first capacitor, and the second branch comprises the second capacitor. The first capacitor may discharge the first node according to the coupling effect, and the second capacitor may charge the second node according to the coupling effect, such that the level of the first control signal may be inverted normally, thereby ensuring that the output circuit may normally output the second level signal having a higher voltage level.

The present disclosure provides a level shifter, a memory, a memory system, and an electronic apparatus.

In a first aspect, the present disclosure provides a level shifter, comprising:
an input circuit, a shifter and an output circuit that are coupled sequentially, wherein the input circuit is configured to generate a first input signal in response to a first level signal; and
a regulation circuit coupled to the input circuit and the shifter separately, wherein the regulation circuit is configured to regulate a first control signal output by the shifter in response to the first input signal, wherein a voltage domain of the shifter is different from a voltage domain of the input circuit; and
the output circuit is configured to output a second level signal in response to the regulated first control signal, wherein a voltage level of the second level signal is higher than a voltage level of the first level signal.

In some examples, the input circuit is configured to generate the first input signal with an inverted phase to the first level signal in response to the first level signal, wherein a first output terminal of the input circuit is configured to output the first input signal;
the shifter comprises a feedback circuit coupled to a first power supply terminal and a first node of the shifter separately, wherein the feedback circuit is configured to provide a power supply voltage level of the first power supply terminal to the first node; and
the regulation circuit comprises a first branch coupled to the first node and the first output terminal of the input circuit, wherein the first branch is configured to discharge the first node in response to the first input signal, so as to regulate the first control signal output by the shifter.

In some examples, the input circuit is further configured to generate a second input signal with an inverted phase to the first input signal in response to the first input signal, wherein a second output terminal of the input circuit is configured to output the second input signal; and
the regulation circuit further comprises a second branch coupled to a second node of the shifter and the second output terminal of the input circuit, wherein the second branch is configured to regulate a voltage level of the second node in response to the second input signal, such that the feedback circuit stops providing the power supply voltage level to the first node; and the feedback circuit is coupled to the first power supply terminal and the second node separately.

In some examples, the second branch is configured to charge the second node in response to the second input signal until the first node is disconnected from the first power supply terminal. In some examples, the feedback circuit comprises:
a first transistor, wherein a first terminal of the first transistor is coupled to the first power supply terminal; a second terminal of the first transistor is coupled to the first node; and a control terminal of the first transistor is coupled to the second node; and
a second transistor, wherein a first terminal of the second transistor is coupled to the first power supply terminal; a second terminal of the second transistor is coupled to the second node;
and a control terminal of the second transistor is coupled to the first node.

In some examples, the first branch comprises a first capacitor; and the second branch comprises a second capacitor.

In some examples, the shifter further comprises a pull-down circuit comprising:
a third transistor, wherein a first terminal of the third transistor is coupled to the first node;
a second terminal of the third transistor is coupled to a ground terminal; and a control terminal of the third transistor is coupled to the second output terminal of the input circuit; and
a fourth transistor, wherein a first terminal of the fourth transistor is coupled to the second node; a second terminal of the fourth transistor is coupled to the ground terminal; and a control terminal of the fourth transistor is coupled to the first output terminal of the input circuit.

In some examples, a threshold voltage of the third transistor is higher than a voltage level of the second input signal.

In some examples, the third transistor and the fourth transistor are NMOS transistors; and the input circuit comprises at least one NMOS transistor, wherein a threshold voltage of the third transistor and a threshold voltage of the fourth transistor are both the same as a threshold voltage of the NMOS transistor in the input circuit.

In some examples, the input circuit comprises at least one phase inverter.

In a second aspect, the present disclosure provides a memory, comprising a page buffer, a control logic circuit, and a level shifter, wherein the level shifter is coupled between the control logic circuit and the page buffer, and the level shifter comprises:
a first phase inverter and a second phase inverter connected sequentially in series, wherein the first phase inverter is configured to generate a first input signal in response to a first level signal output by the control logic circuit;
a first transistor, wherein a first terminal of the first transistor is coupled to a first power supply terminal; a second terminal of the first transistor is coupled to a first node; a control terminal of the first transistor is coupled to a second node; and a voltage of a second power supply terminal coupled to the first phase inverter is different from a voltage of the first power supply terminal;
a second transistor, wherein a first terminal of the second transistor is coupled to the first power supply terminal; a second terminal of the second transistor is coupled to the second node;
and a control terminal of the second transistor is coupled to the first node;
a first capacitor coupled to the first node and an output terminal of the first phase inverter, wherein the first capacitor is configured to regulate a first control signal output by the first node in response to the first input signal;
a second capacitor coupled to the second node and an output terminal of the second phase inverter; and
a third phase inverter coupled to the first node, wherein the third phase inverter is configured to output a second level signal in response to the regulated first control signal, wherein a voltage level of the second level signal is higher than a voltage level of the first level signal.

In some examples, the second phase inverter is configured to generate a second input signal in response to the first input signal; and
the second capacitor is configured to regulate a voltage level of the second node in response to the second input signal, so as to turn off the first transistor.

In some examples, the first capacitor is configured to discharge the first node in response to the first input signal, so as to regulate the first control signal output by the first node; and
the second capacitor is configured to charge the second node in response to the second input signal until the first transistor is turned off.

In some examples, the level shifter further comprises:
a third transistor, wherein a first terminal of the third transistor is coupled to the first node; a second terminal of the third transistor is coupled to a ground terminal; and a control terminal of the third transistor is coupled to the output terminal of the second phase inverter; and
a fourth transistor, wherein a first terminal of the fourth transistor is coupled to the second node; a second terminal of the fourth transistor is coupled to the ground terminal; and a control terminal of the fourth transistor is coupled to the output terminal of the first phase inverter.

In some examples, the first transistor and the second transistor are PMOS transistors, and the third transistor and the fourth transistor are NMOS transistors.

In some examples, a threshold voltage of the third transistor is higher than a voltage level of the second input signal.

In some examples, the third transistor and the fourth transistor are NMOS transistors; and a threshold voltage of the third transistor, a threshold voltage of the fourth transistor, a threshold voltage of an NMOS transistor in the first phase inverter and a threshold voltage of an NMOS transistor in the second phase inverter are all the same.

In some examples, the page buffer comprises a bias circuit; the level shifter is coupled between the bias circuit and the control logic circuit; and
the bias circuit is configured to apply a bias voltage to a bit line in response to the second level signal.

In a third aspect, the present disclosure provides a memory system, comprising:
the memory described in any of the above examples; and
a memory controller coupled to the memory.

In a fourth aspect, the present disclosure provides an electronic apparatus, comprising the memory system described in the above example.

In the examples of the present disclosure, the voltage domain of the shifter is different from the voltage domain of the input circuit, and the regulation circuit is configured to regulate the first control signal output by the shifter in response to the first input signal; and the output circuit is configured to output the second level signal in response to the regulated first control signal. As such, in case of a large voltage difference between a voltage at the power supply terminal coupled to the shifter and a voltage at the power supply terminal coupled to the input circuit, the regulation circuit may regulate the level of the first control signal, such that the level of the first control signal may be inverted normally, ensuring that the output circuit may normally output the second level signal having a higher voltage level, so as to improve the reliability of the level shifter.

It is to be understood that “one example” and “an example” mentioned throughout the specification mean that specific features, structures or characteristics related to the example are included in at least one example of the present disclosure. Therefore, “in one example” or “in an example” presented throughout this specification does not necessarily refer to the same example. In addition, these specific features, structures or characteristics may be combined in one or more examples in any suitable manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are used for description only, and do not represent advantages or disadvantages of the examples.

The above descriptions are merely some implementations of the present disclosure, and not intended to limit the protection scope of the present disclosure. Any equivalent structure transformation made by using the specification and drawings of the present disclosure under the concept of the present disclosure or direct/indirect application to other related technical fields are encompassed within the protection scope of the present disclosure.

What is claimed is:

1. A level shifter, comprising:
an input circuit, a shifter and an output circuit that are coupled sequentially, wherein the input circuit is configured to generate a first input signal in response to a first level signal;
a regulation circuit coupled to the input circuit and the shifter separately, wherein the regulation circuit is configured to regulate a first control signal output by the shifter in response to the first input signal, wherein a voltage domain of the shifter is different from a voltage domain of the input circuit; and
the output circuit is configured to output a second level signal in response to the regulated first control signal, wherein a voltage level of the second level signal is higher than a voltage level of the first level signal.

2. The level shifter of claim 1, wherein the input circuit is configured to generate the first input signal with an inverted phase to the first level signal in response to the first level signal, wherein a first output terminal of the input circuit is configured to output the first input signal;
the shifter includes a feedback circuit coupled to a first power supply terminal and a first node of the shifter separately, wherein the feedback circuit is configured to provide a power supply voltage level of the first power supply terminal to the first node; and
the regulation circuit includes a first branch coupled to the first node and the first output terminal of the input circuit, wherein the first branch is configured to discharge the first node in response to the first input signal, so as to regulate the first control signal output by the shifter.

3. The level shifter of claim 2, wherein the input circuit is further configured to generate a second input signal with an inverted phase to the first input signal in response to the first input signal, wherein a second output terminal of the input circuit is configured to output the second input signal; and
the regulation circuit further includes a second branch coupled to a second node of the shifter and the second output terminal of the input circuit, wherein the second branch is configured to regulate a voltage level of the second node in response to the second input signal, such that the feedback circuit stops providing the power supply voltage level to the first node, and the feedback circuit is coupled to the first power supply terminal and the second node separately.

4. The level shifter of claim 3, wherein the second branch is configured to charge the second node in response to the second input signal until the first node is disconnected from the first power supply terminal.

5. The level shifter of claim 3, wherein the feedback circuit includes:
a first transistor, wherein a first terminal of the first transistor is coupled to the first power supply terminal, a second terminal of the first transistor is coupled to the first node, and a control terminal of the first transistor is coupled to the second node; and
a second transistor, wherein a first terminal of the second transistor is coupled to the first power supply terminal, a second terminal of the second transistor is coupled to the second node, and a control terminal of the second transistor is coupled to the first node.

6. The level shifter of claim 3, wherein the first branch includes a first capacitor; and the second branch includes a second capacitor.

7. The level shifter of claim 3, wherein the shifter further includes a pull-down circuit including:
a third transistor, wherein a first terminal of the third transistor is coupled to the first node, a second terminal of the third transistor is coupled to a ground terminal, and a control terminal of the third transistor is coupled to the second output terminal of the input circuit; and
a fourth transistor, wherein a first terminal of the fourth transistor is coupled to the second node, a second terminal of the fourth transistor is coupled to the ground terminal, and a control terminal of the fourth transistor is coupled to the first output terminal of the input circuit.

8. The level shifter of claim 7, wherein a threshold voltage of the third transistor is higher than a voltage level of the second input signal.

9. The level shifter of claim 7, wherein the third transistor and the fourth transistor are N-channel metal-oxide-semiconductor (NMOS) transistors, and the input circuit includes at least one NMOS transistor, wherein a threshold voltage of the third transistor and a threshold voltage of the fourth transistor are both the same as a threshold voltage of the NMOS transistor in the input circuit.

10. The level shifter of claim 1, wherein the input circuit includes at least one phase inverter.

11. A memory, including a page buffer, a control logic circuit, and a level shifter, wherein the level shifter is coupled between the control logic circuit and the page buffer, and the level shifter includes:
a first phase inverter and a second phase inverter connected sequentially in series, wherein the first phase inverter is configured to generate a first input signal in response to a first level signal output by the control logic circuit;
a first transistor, wherein a first terminal of the first transistor is coupled to a first power supply terminal, a second terminal of the first transistor is coupled to a first node, a control terminal of the first transistor is coupled to a second node, and a voltage of a second power supply terminal coupled to the first phase inverter is different from a voltage of the first power supply terminal;
a second transistor, wherein a first terminal of the second transistor is coupled to the first power supply terminal, a second terminal of the second transistor is coupled to the second node, and a control terminal of the second transistor is coupled to the first node;
a first capacitor coupled to the first node and an output terminal of the first phase inverter, wherein the first capacitor is configured to regulate a first control signal output by the first node in response to the first input signal;
a second capacitor coupled to the second node and an output terminal of the second phase inverter; and
a third phase inverter coupled to the first node, wherein the third phase inverter is configured to output a second level signal in response to the regulated first control signal, wherein a voltage level of the second level signal is higher than a voltage level of the first level signal.

12. The memory of claim 11, wherein the second phase inverter is configured to generate a second input signal in response to the first input signal; and
the second capacitor is configured to regulate a voltage level of the second node in response to the second input signal, so as to turn off the first transistor.

13. The memory of claim 12, wherein the first capacitor is configured to discharge the first node in response to the first input signal, so as to regulate the first control signal output by the first node; and
the second capacitor is configured to charge the second node in response to the second input signal until the first transistor is turned off.

14. The memory of claim 12, wherein the level shifter further includes:
a third transistor, wherein a first terminal of the third transistor is coupled to the first node, a second terminal of the third transistor is coupled to a ground terminal, and a control terminal of the third transistor is coupled to the output terminal of the second phase inverter; and
a fourth transistor, wherein a first terminal of the fourth transistor is coupled to the second node, a second terminal of the fourth transistor is coupled to the ground terminal, and a control terminal of the fourth transistor is coupled to the output terminal of the first phase inverter.

15. The memory of claim 14, wherein the first transistor and the second transistor are P-channel metal-oxide-semiconductor (PMOS) transistors, and the third transistor and the fourth transistor are N-channel metal-oxide-semiconductor (NMOS) transistors.

16. The memory of claim 14, wherein a threshold voltage of the third transistor is higher than a voltage level of the second input signal.

17. The memory of claim 14, wherein the third transistor and the fourth transistor are N-channel metal-oxide-semiconductor (NMOS) transistors, and a threshold voltage of the third transistor, a threshold voltage of the fourth transistor, a threshold voltage of an N-channel metal-oxide-semiconductor (NMOS) transistor in the first phase inverter and a threshold voltage of an NMOS transistor in the second phase inverter are the same.

18. The memory of claim 11, wherein the page buffer includes a bias circuit, and the level shifter is coupled between the bias circuit and the control logic circuit; and
the bias circuit is configured to apply a bias voltage to a bit line in response to the second level signal.

19. A memory system, comprising:
a memory, including a page buffer, a control logic circuit, and a level shifter, wherein the level shifter is coupled between the control logic circuit and the page buffer, and the level shifter includes:
a first phase inverter and a second phase inverter connected sequentially in series, wherein the first phase inverter is configured to generate a first input signal in response to a first level signal output by the control logic circuit;
a first transistor, wherein a first terminal of the first transistor is coupled to a first power supply terminal, a second terminal of the first transistor is coupled to a first node, a control terminal of the first transistor is coupled to a second node, and a voltage of a second power supply terminal coupled to the first phase inverter is different from a voltage of the first power supply terminal;
a second transistor, wherein a first terminal of the second transistor is coupled to the first power supply terminal, a second terminal of the second transistor is coupled to the second node, and a control terminal of the second transistor is coupled to the first node;
a first capacitor coupled to the first node and an output terminal of the first phase inverter, wherein the first capacitor is configured to regulate a first control signal output by the first node in response to the first input signal;
a second capacitor coupled to the second node and an output terminal of the second phase inverter; and
a third phase inverter coupled to the first node, wherein the third phase inverter is configured to output a second level signal in response to the regulated first control signal, wherein a voltage level of the second level signal is higher than a voltage level of the first level signal; and
a memory controller coupled to the memory.

20. The memory system of claim 19, wherein an input circuit is configured to generate the first input signal with an inverted phase to the first level signal in response to the first level signal, wherein a first output terminal of the input circuit is configured to output the first input signal;
the level shifter includes a feedback circuit coupled to a first power supply terminal and a first node of the level shifter separately, wherein the feedback circuit is configured to provide a power supply voltage level of the first power supply terminal to the first node; and
a regulation circuit includes a first branch coupled to the first node and the first output terminal of the input circuit, wherein the first branch is configured to discharge the first node in response to the first input signal, so as to regulate the first control signal output by the level shifter.
